(19) United States
(12) Patent Application Publication
(10) Pub. No.: US 2014/0037858 A1
(43) Pub. Date: Feb. 6, 2014

(54) ANISOTROPIC SURFACE ENERGY MODULATION BY ION IMPLANTATION

(71) Applicants: Tristan Ma, Lexington, MA (US); Ludovic Godet, Boston, MA (US); Christopher Hatem, Hampton, NH (US)

(72) Inventors: Tristan Ma, Lexington, MA (US); Ludovic Godet, Boston, MA (US); Christopher Hatem, Hampton, NH (US)

(73) Assignee: VARIAN SEMICONDUCTOR EQUIPMENT ASSOCIATES, INC., Gloucester, MA (US)

(21) Appl. No.: 13/563,046

(22) Filed: Jul. 31, 2012

(51) Int. Cl. C23C 14/48

(52) U.S. Cl. 427/523

(57) ABSTRACT

Methods of modulating a material's surface energies through the implantation of ions, such as by using a plasma processing apparatus with a plasma sheath modifier, are disclosed. Two or more ion implants may be performed, where the implant regions of two of the ion implants overlap. The species implanted by a first implant may increase the hydrophobicity of the surface, wherein the species implanted by the second implant may decrease the hydrophobicity of the surface. In this way, a workpiece can be implanted such that different portions of its surface have different surface energies.

### FIELD

This invention relates to ion implantation and, more particularly, to ion implantation for precision material modification.

### BACKGROUND

Ion implantation is a standard technique for introducing material into a workpiece. A desired implant material is ionized in an ion source, the ions are accelerated to form an ion beam of prescribed energy, and the ion beam is directed at the surface of the workpiece. The energetic ions in the beam penetrate into the bulk of the workpiece material and affect both the surface and depth of the workpiece material under certain conditions.

While ion implantation is typically used to alter the electrical properties of a workpiece, it can also be used to affect other material properties, such as resistance to specific chemicals, adhesion, hydrophobicity, hydrophilicity, and others.

Inkjet printing is a technique that ejects liquid ink onto paper. The inkjet print head (or cartridge) has nozzles that are about the size of a needlepoint through which the ink is ejected. In some embodiments, the head may include multiple nozzles to accommodate a plurality of colored inks. The printing process may involve a nucleation step using the ink, bubble growth, ejection of an ink drop, and refilling of the inkjet head.

Printing resolution and lifetime are both limited by the inkjet aperture size. Smaller apertures can provide higher resolution, but the lifetime is reduced due to clogging of the aperture with the ink. Applying inkjet printing to new fields such as, biochips, metal wiring, liquid crystal displays (LCDs), organic light-emitting diodes (OLEDs), or microelectromechanical systems (MEMS) devices is being investigated. However, suitable printing heads are required for each application before widespread adoption can occur. For example, ejection of high viscosity ink droplets may need to provide high precision, high frequency, no chemical reaction, and no clogging. Thus, it may be beneficial to affect the properties of the material used to create the print head to minimize the interaction between the ink and the print head.

Electrowetting displays may also utilize workpieces where various portions of the workpiece have different surface energies. These displays have very low energy consumption and excellent indoor/outdoor usability. To control the behavior of the liquid in the pixel cell of an electrowetting display, it may be beneficial if the sidewalls and the top and bottom surfaces of that cell have different surface energies.

Another application where affecting material properties may be beneficial is MEMS and nanoelectromechanical systems (NEMS) devices. MEMS devices relate to small mechanical devices driven by electricity. NEMS devices relate to devices integrating electrical and mechanical functionality on the nanoscale. Examples of these devices are accelerometers and gyroscopes, though there are countless others. MEMS and NEMS processing is extremely complex. One difficulty is that precise material modification to locally affect material properties has not been effectively demonstrated. In some MEMS and NEMS devices, fluids pass through portions of the device. Therefore, it may be important that these surfaces are moisture resistant or hydrophobic. Additionally, it may be important to reduce stiction in portions of these devices.

In other technology applications, surface energy may need to be modulated to achieve the desired surface characteristics, such as desired microfluidic behaviors, and enhanced surface compatibility with biomolecules in bio-sensor applications.

Therefore, in each of these examples, it would be beneficial to have an improved method of modulating surface energies. Such an improved method could then be applied to various technologies, including inkjet printing, biochips, electrowetting displays, and MEMS and NEMS devices.

### SUMMARY

Methods of modulating a material's surface energies through the implantation of ions, such as by using a plasma processing apparatus with a plasma sheath modifier, are disclosed. Two or more ion implants may be performed, where the implant regions of two of the ion implants overlap. The species implanted by a first implant may increase the hydrophobicity of the surface, wherein the species implanted by the second implant may decrease the hydrophobicity of the surface. In this way, a workpiece can be implanted such that different portions of its surface have different surface energies.

### BRIEF DESCRIPTION OF THE DRAWINGS

For a better understanding of the present disclosure, reference is made to the accompanying drawings, which are incorporated herein by reference and in which:

FIG. 1 is a block diagram of a plasma processing apparatus having a plasma sheath modifier;

FIG. 2 illustrates surface energy modulation in both directions;

FIGS. 3A-C are TEM cross-sectional side views of a workpiece subjected to ion implantation according to one embodiment;

FIG. 3D is a graph showing the relative concentration of workpiece material and implanted species as a function of depth;

FIG. 4 is a graph showing the water contact angle of various workpieces over time;

FIG. 5A-B show the effects of two implants on a workpiece;

FIG. 6A-B show a multi-step process to implant ions to create various surface energies in different parts of a three dimensional workpiece;

FIG. 8 shows a planar surface having a first implant region and a second implant region inside the first region; and

FIG. 9 shows a planar surface having a first implant region and a second implant region, which overlap.

### DETAILED DESCRIPTION

The embodiments are described herein in connection with specific materials and devices, but these embodiments should not be limited merely to the materials and devices listed. For example, some of the embodiments are described herein in connection with MEMS and NEMS, but these embodiments also may be used with other devices. Similarly, some of the embodiments are described herein in connection with printers such as inkjet printers, but these embodiments also may be used with other printing devices. These inkjet printers or other printing devices can be used for paper or other applications known to a person skilled in the art. While a specific type of implanter is disclosed, other ion implantation systems known to those skilled in the art that can focus an ion beam or that can implant particular regions of a workpiece with or without a mask on, above, or a distance from the workpiece also may be used in the embodiments described herein. While the term “hydrophobic” is used, throughout, it may be advantageous to render a surface hydrophilic instead. Thus, the invention is not limited to the specific embodiments described below.

While a beamline or plasma doping tool may be used to implant ions to affect a material's properties, a plasma processing apparatus having a plasma sheath modifier may be used. This has an advantage that selective implantation of 2D or 3D surfaces may be performed without using photoresist, other hard masks, or proximity masks. This sort of patterned implant reduces processing time and manufacturing costs. Scanning the workpiece or device to be implanted may be combined with biasing such a workpiece or device or changing the plasma parameters to accomplish this selective implantation.

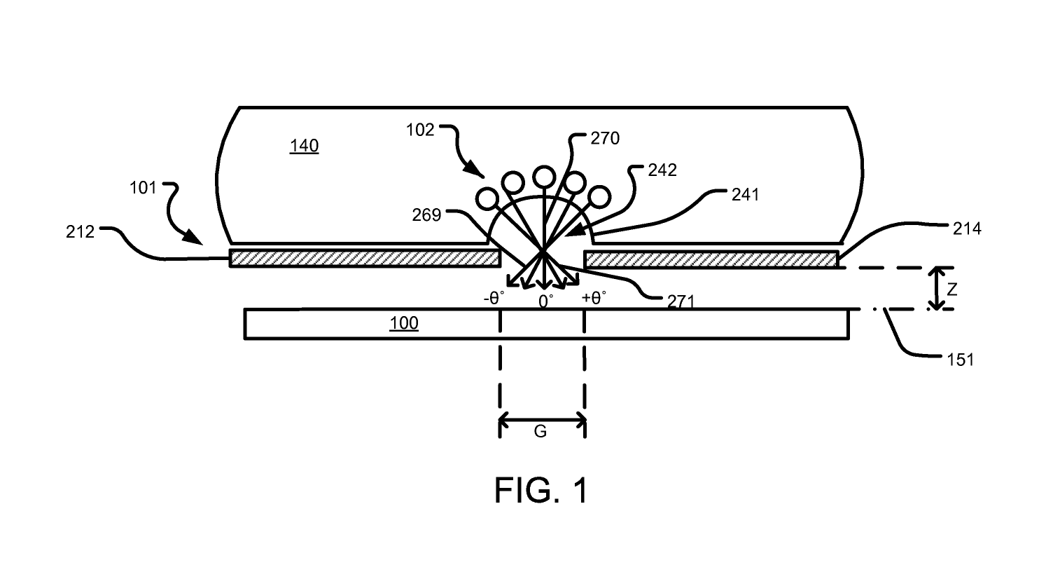

FIG. 1 is a block diagram of a plasma processing apparatus having a plasma sheath modifier. The plasma 140 is generated as is known in the art. This plasma 140 is generally a quasi-neutral collection of ions and electrons. The ions typically have a positive charge while the electrons have a negative charge. The plasma 140 may have an electric field of, for example, approximately 0 V/cm in the bulk of the plasma 140. In a system containing the plasma 140, ions 102 from the plasma 140 are attracted toward a workpiece 100. These ions 102 may be attracted with sufficient energy to be implanted into the workpiece 100. The plasma 140 is bounded by a region proximate the workpiece 100 referred to as a plasma sheath 242. The plasma sheath 242 is a region that has fewer electrons than the plasma 140. Hence, the differences between the negative and positive charges cause a sheath potential in the plasma sheath 242. The light emission from this plasma sheath 242 is less intense than the plasma 140 because fewer electrons are present and, hence, few excitation-relaxation collisions occur. Thus, the plasma sheath 242 is sometimes referred to as “dark space.”

The plasma sheath modifier 101 is configured to modify an electric field within the plasma sheath 242 to control a shape of a boundary 241 between the plasma 140 and the plasma sheath 242. Accordingly, ions 102 that are attracted from the plasma 140 across the plasma sheath 242 may strike the workpiece 100 at a large range of incident angles. This plasma sheath modifier 101 may be referred to as, for example, a focusing plate or sheath engineering plate.

In the embodiment of FIG. 1, the plasma sheath modifier 101 includes a pair of panels 212 and 214 defining an aperture there between having a horizontal spacing (G). The panels 212 and 214 may be an insulator, semiconductor, or conductor. In other embodiments, the plasma sheath modifier 101 may include only one panel or more than two panels. The panels 212 and 214 may be a pair of sheets having a thin, flat shape. In other embodiments, the panels 212 and 214 may be other shapes such as tube-shaped, wedge-shaped, and/or have a beveled edge proximate the aperture. The panels 212 and 214 also may be positioned a vertical spacing (Z) above the plane 151 defined by the front surface of the workpiece 100. In one embodiment, the vertical spacing (Z) may be about 1.0 to 10.0 mm.

Ions 102 may be attracted from the plasma 140 across the plasma sheath 242 by different mechanisms. In one instance, the workpiece 100 is biased to attract ions 102 from the plasma 140 across the plasma sheath 242. In another instance, a plasma source that generates the plasma 140 and walls surrounding the plasma 140 are biased positively and the workpiece 100 may be grounded. The biasing may be pulsed in one particular embodiment. In yet another instance, electric or magnetic fields are used to attract ions 102 from the plasma 140 toward the workpiece 100.

Advantageously, the plasma sheath modifier 101 modifies the electric field within the plasma sheath 242 to control a shape of the boundary 241 between the plasma 140 and the plasma sheath 242. The boundary 241 between the plasma 140 and the plasma sheath 242 may have a convex shape relative to the plane 151 in one instance. When the workpiece 100 is biased, for example, the ions 102 are attracted across the plasma sheath 242 through the aperture between the panels 212 and 214 at a large range of incident angles. For instance, ions 102 following trajectory path 271 may strike the workpiece 100 at an angle of +θ° relative a line normal to the plane 151. Ions 102 following trajectory path 270 may strike the workpiece 100 at about an angle of 0° relative to a line normal to the same plane 151. Ions 102 following trajectory path 269 may strike the workpiece 100 an angle of −θ° relative to a line normal to the plane 151. Accordingly, the range of incident angles may be between +θ° and −θ° centered about 0°. In addition, some ion trajectories paths such as paths 269 and 271 may cross each other. Depending on a number of factors including, but not limited to, the horizontal spacing (G) between the panels 212 and 214, the vertical spacing (Z) of the panels 212 and 214 above the plane 151, the dielectric constant of the panels 212 and 214, or other process parameters of the plasma 140, the range of incident angles (θ) may be between +60° and −60° centered about 0°. The plasma processing apparatus of FIG. 1 can be used to affect the properties of a material.

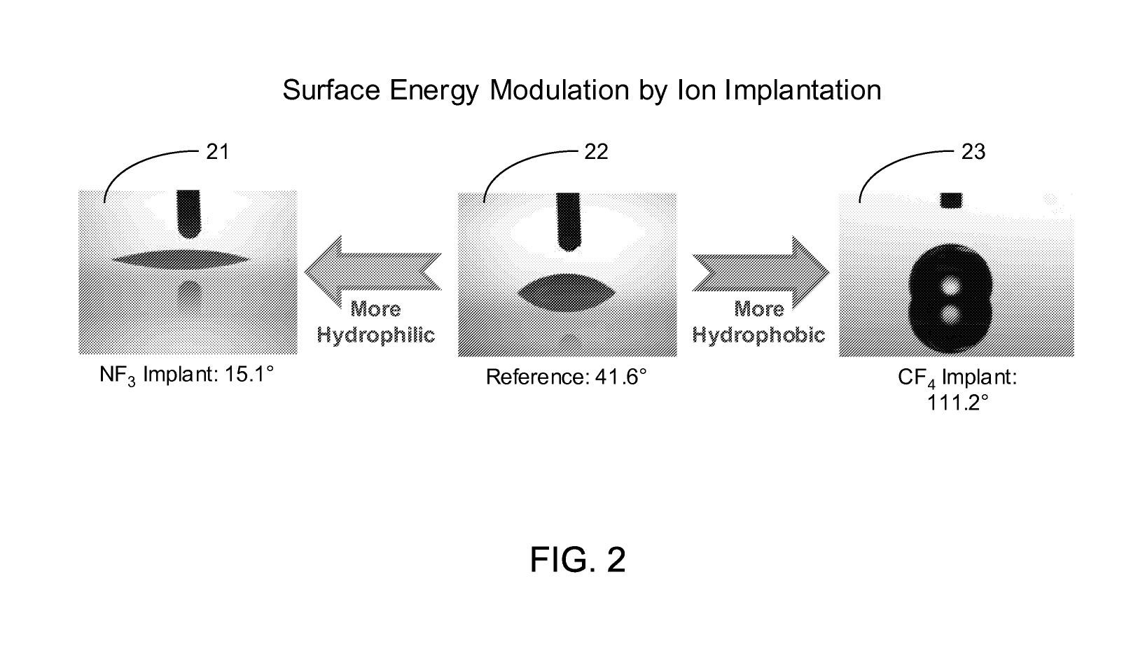

In one embodiment, use of multi-angle ion implantation can modify the property of a surface of a workpiece. This workpiece may be fabricated of, for example, silicon, silicon oxide, silicon nitride, silicon carbide, tetraethyl orthosilicate (TEOS), polyimide, quartz glass, PECVD carbon film, and KAPTON®. FIG. 2 illustrates the surface energy modulation that can be caused by ion implantation. A surface was rendered hydrophilic after implant of NF₃ and hydrophobic after implant of CF₄ using a plasma doping tool. A reference material of Si wafer, shown in the center of FIG. 2, has an initial water contact angle of 41.6°. The accompanying illustration 22 depicts the shape of a water droplet on the material. By implanting the material with NF₃, the contact angle was reduced to 15.1°, indicating that the material has become more hydrophilic. As shown in the upper illustration 21, the water droplet is more spread across the surface of the material. Conversely, the bottom illustration 23 shows the effect of a CF₄ implant. In this case, the contact angle increases to 111.2°, indicating a high degree of hydrophobicity. As shown in FIG. 2, ion implant can change a surface to be hydrophobic or hydrophilic. Thus, the adhesion of a certain material to the surface can be changed. Using a multi-angle ion implant can also enable changing the hydrophobic/hydrophilic or porosity properties of a 3D structure.

Many different species, such as CF₄, CHF₃, C₃F₆, BF₃, SF₆, SiF₄, NF₃, He, and O₂, can be implanted for the purpose of modulating surface energies to make the surface either more hydrophobic or more hydrophilic. For example, surfaces can be made more hydrophobic with the implant of certain species, such as CF₄, as described above. However, other species, such as fluorinated carbons (including CHF₃ and CₓF_{y}), BF₃, SF₆ and SiF₄ may also be used to create a more hydrophobic surface. Surfaces can be made more hydrophilic with an implant of NF₃, as described above. However, other species, such as O₂ and He, may also be used. This list of species is not intended to be inclusive, but rather illustrates some of the species that can be used to affect surface energy. The species used may depend on the underlying workpiece material and other considerations.

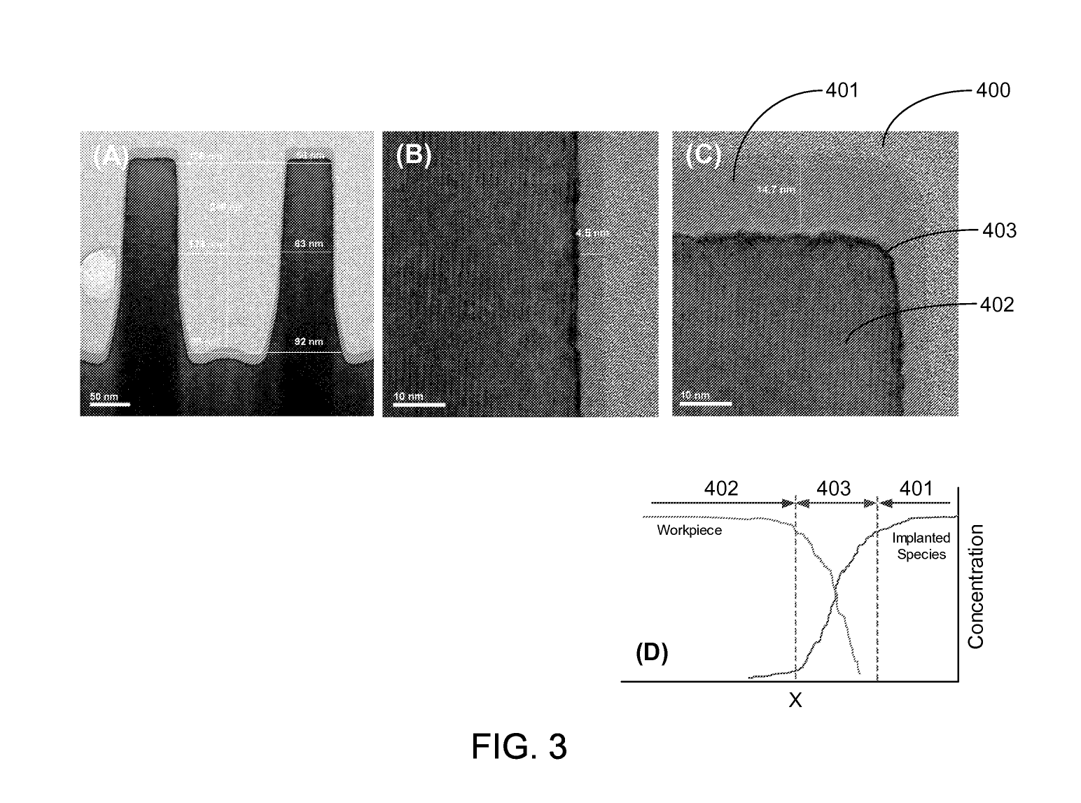

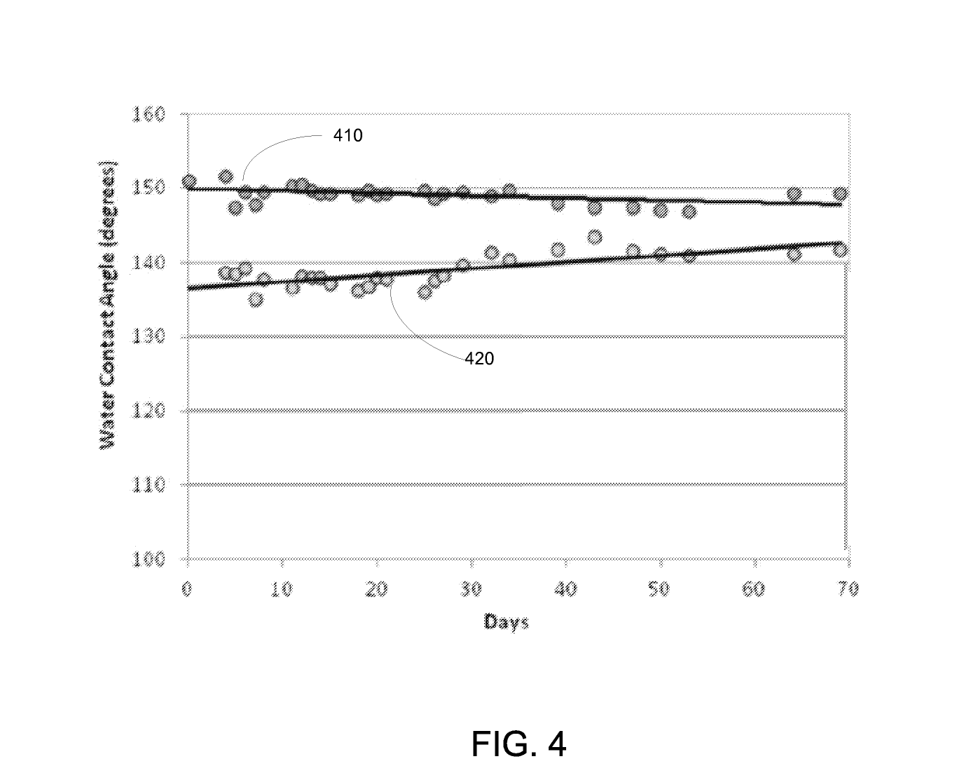

The use of ion implantation has other advantages over deposition methods, such as CVD or PVD. The acceleration of ions into the workpieces leads to an alteration of the composition of the surface. By selecting proper implant conditions, a gradient may be created in the workpiece, where the interior of the workpiece is devoid of ions, and the outer surface or coating is composed only of deposited ions. FIGS. 3A-C shows a series of TEM images of a three dimensional trench structure, showing the effects of ion implantation. In one embodiment, to implant the top, bottom, and sidewall surfaces of the three-dimensional trench structure, CF₄ gas is used with a plasma processing tool, such as the implanter illustrated in FIG. 1, to process the structure wafers at an extraction voltage of 1 kV, a RF power of 800 Watts, a dose of 1.0E16, and a duty cycle of 10%. This provides an ion angular distribution of about +/−25 degrees, which allows the ion beams to reach the trench sidewalls.

FIG. 3B shows an enlargement of the sidewall of the trench of FIG. 3A, while FIG. 3C shows the top corner of the trench of FIG. 3A. As best seen in FIG. 3C, the light region 400 represents the coating used during TEM sample preparation. The dark region 402 represents the original workpiece, such as silicon. Region 401 between these regions represents a deposition layer on the surface of the workpiece, comprised of the implanted species. The narrow, very dark line between 401 and 402 represents an amorphous interfacial layer 403, where implanted ions are intermingled with the underlying workpiece. A graph representing a typical SIMS depth profile is shown in FIG. 3D, illustrating the relationship between this interfacial layer 403, the implanted layer 401, and the workpiece region 402. This structure may result in stronger and more durable surface properties. Long term mechanical durability may be enhanced by creating such a transitional surface region which has implanted ions.

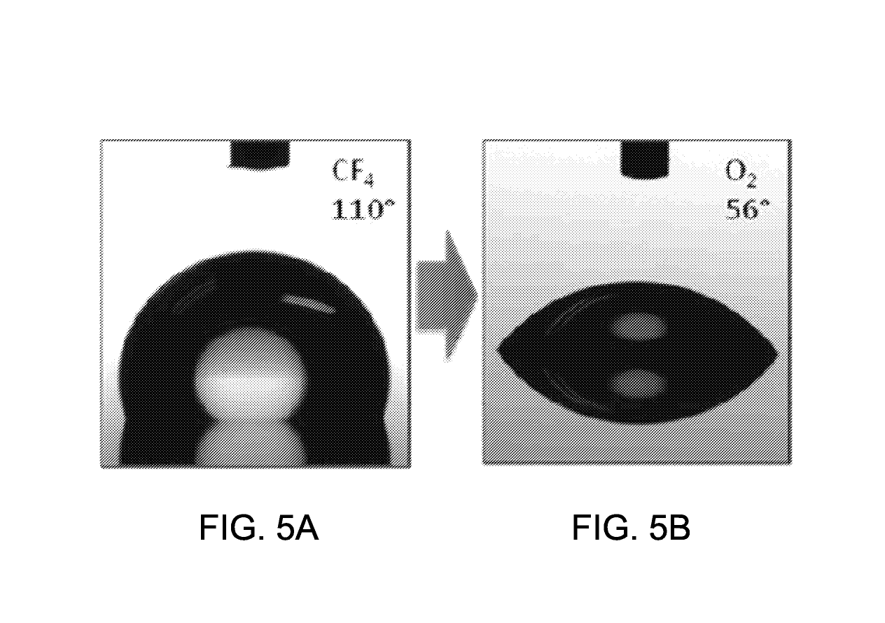

FIG. 4 shows the water contact angle of two types of previously implanted workpieces as a function of time. Line 410 represents the water contact angle of a silicon workpiece that was previously implanted with CF₄ as a function of time. Line 420 represent the contact angle of a KAPTON® (polyimide) workpiece that was previously implanted with CF₄ as a function of time. Note that after 70 days, due to the mechanical durability created by the transitional surface region, the contact angle has not decreased and the observed variation is less than 5%.

Furthermore, the use of ion implantation allows precise control of the surface characteristics. For example, by controlling the dose of implanted ions, it is possible to create specific characteristics. For example, FIG. 2 shows that, with a certain dose of CF₄, the contact angle of a particular workpiece can be increased to 111.2°. However, a lower dose of that implanted species can be used and would result in a contact angle less than that achieved in FIG. 2, but greater than the characteristic contact angle of the material. Thus, if a specific contact angle is required, the use of ion implantation can ensure that this desired contact angle is achieved.

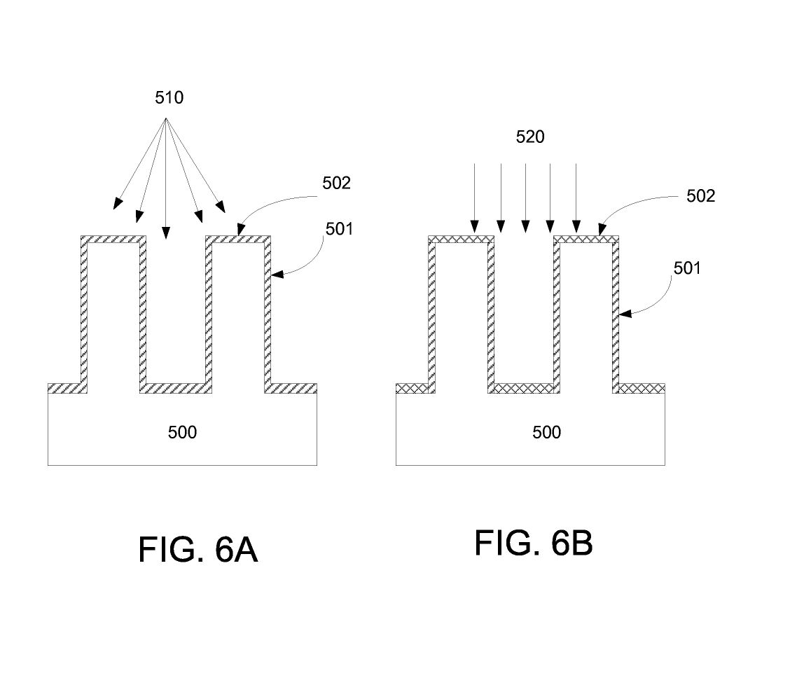

Additionally, the various implants described above can be performed in series to modulate the surface energy of the workpiece. For example, as described above, an implant of CF₄ can be used to make the surface of a workpiece more hydrophobic. Interestingly, a subsequent implant of a second species, such as oxygen, can reverse the degree of hydrophobicity of the surface. FIG. 5A represents the contact angle of silicon after an implant of CF₄. This implant may be performed using a plasma processing tool at an energy of 500 eV and a dose of 5.0E15. This implant changes the water contact angle from about 30° (intrinsic property of silicon) to about 110°. FIG. 5B represents the contact angle of the implanted silicon of FIG. 5A after a subsequent implant of oxygen. This implant may be performed using the same plasma processing tool at an energy of 1 keV and a dose of 5.0E15. Note that the water contact angle has been reduced to about 56°. Thus, it is possible to change the hydrophobicity (or hydrophilicity) of the workpiece, after an ion implant has already been performed. Thus, the second implant serves to “undo” or reverse the effects of the first ion implant.

Thus, a multi-step approach may be used to create a workpiece having surfaces of different hydrophobic/hydrophilic properties. Such a workpiece may be useful in various applications, such as inkjet printer heads and electrowetting displays. Other applications, such as microfluidic handling devices and biosensors, may also benefit from this technique.

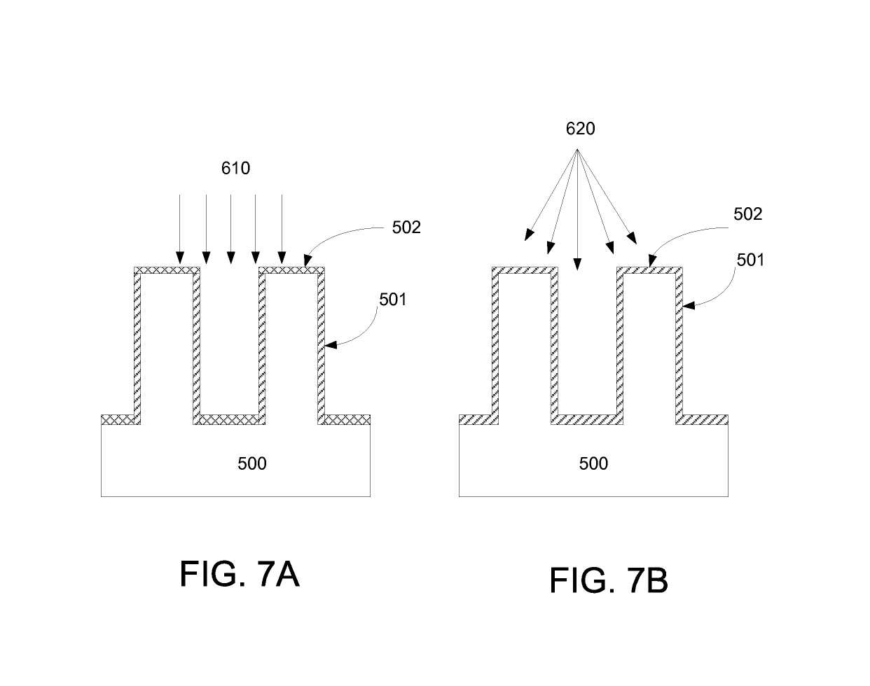

FIGS. 6A-B show a multi-step process that can be utilized to create a workpiece having surfaces of different surface energy. In FIG. 6A, a workpiece 500 is shown. This workpiece may have vertical surfaces 501 and horizontal surfaces 502, although the process is applicable to other configurations as well. A first implant region of the workpiece is subjected to a first implant 510 of a first species. In this illustration, this first implant 510 is performed at a variety of implant angles so as to implant the horizontal surfaces 502 and the vertical surfaces 501 simultaneously. Thus, the first implant region comprises the entirety of the surface of the workpiece. This first implant 510 may be CF₄, so as to make the horizontal surfaces 502 and vertical surfaces 501 hydrophobic. In other embodiments, this first implant 510 may be a different species that makes the surface hydrophobic. In some embodiments, this first implant 510 is performed using the apparatus of FIG. 1, which allows a variety of implant angles.

After the first implant 510 is performed, the horizontal surfaces 502 and the vertical surfaces 501 are all hydrophobic. Following this, a second implant 520, using a second species, is performed. This second implant 520 may be performed on only some of the surfaces of the workpiece 500. For example, in FIG. 6B, a second implant 520 having an implant angle that is perpendicular to the workpiece 500 is performed, such that the ions only implant the horizontal surfaces 502. This second species may comprise ions that increase the hydrophilicity of the workpiece. The second species may include oxygen, helium, and other suitable ions. In this example, the resulting workpiece 500 would have hydrophobic sidewalls (represented by the vertical surfaces 501), and less hydrophobic (or hydrophilic) top and bottom surfaces (represented by the horizontal surfaces 502).

While FIGS. 6A-B show a first implant 510 which makes the surfaces hydrophobic and a second implant 520 which makes the top and bottom surfaces hydrophilic, the specific locations of these newly generated surface properties can vary. For example, the first implant 510 may be performed so as to make the horizontal surfaces 502 and the vertical surfaces 501 hydrophilic and the second implant may be performed to make the horizontal surfaces 502 hydrophobic.

Additionally, the first implant 510 need not be performed at a variety of implant angles. For example, in another embodiment, shown in FIG. 7A, the first implant 610 is performed at a single implant angle, such as 90°. The second implant 620 is performed at a variety of implant angles, as shown in FIG. 7B. In some embodiments, the implant 610 can be used to increase the hydrophobicity of the surface 502, while the implant 620 reduces the hydrophobicity of the surfaces 501, 502. In other embodiments, the implant 610 can be used to decrease the hydrophobicity of the surface 502, while the implant 620 increases the hydrophobicity of the surfaces 501, 502.

FIGS. 6A-B and 7A-B show the use of implant angle to create two different implant regions on a 3D structure. A wide range of implant angles is used to create a first implant region which comprises both the horizontal surfaces 502 and the vertical surfaces 501. A narrow range of implant angles is used to create a second implant region which comprises only the horizontal surfaces 502. However, other techniques may be used to create two different implant regions, where a portion of the workpiece 500 is part of both implant regions. For example, shadow masks, photoresist, and other techniques may be used to create two different implant regions.

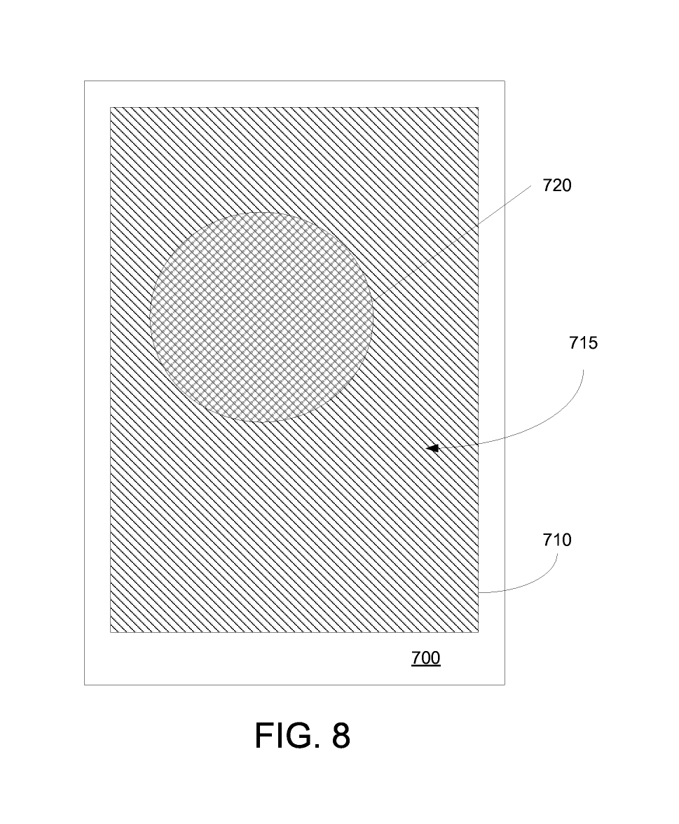

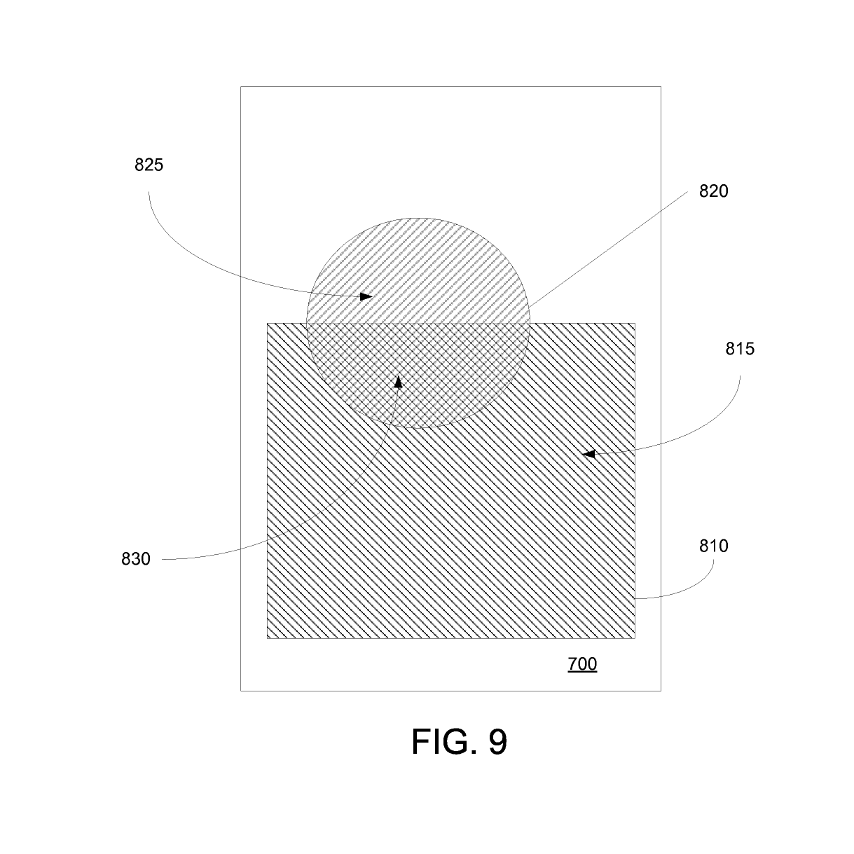

In some embodiments, like that of FIG. 8, the second implant region 720 is inside the first implant region 710. In this embodiment, a workpiece 700 with two different surface energies may be created. The second implant region 720 has one surface energy, and the non-overlapped portion of the first implant region 715 has a second surface energy. In other embodiments, like that of FIG. 9, the second implant region 820 may not be completely inside the first implant region 810. In this embodiment, a workpiece 800 with at least three different implant energies may be created. The non-overlapped portion of the first implant region 815 would have a first surface energy, the non-overlapped portion of the second implant region 825 has a second surface energy, and the overlap 830 between the first implant region and the second implant region would have a third implant energy. Of course, the disclosure is not limited to only two implants. Multiple implants and multiple implant regions are within the scope of the disclosure.

While the first implant using a variety of implant angles may be performed using the apparatus of FIG. 1, other ion implanters may be used. For example, conventional beamline and plasma processing (PLAD) apparatus may also be used.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A method of creating a workpiece having regions of differing surface energies, comprising:
performing a first implant of a first species into a first implant region of said workpiece, wherein said first species increases the hydrophobicity of said first implant region; and
performing a second implant of a second species into a second implant region of said workpiece, wherein said second species reduces the hydrophobicity of said second implant region and wherein at least a portion of said second implant region overlaps said first implant region.

2. The method of claim 1, wherein said workpiece comprises 3D structures and said first implant region comprises vertical surfaces and horizontal surfaces.

3. The method of claim 2, wherein said second implant region comprises horizontal surfaces.

4. The method of claim 2, wherein said first implant is performed using a variety of implant angles.

5. The method of claim 1, wherein said first species is selected from the group consisting of fluorinated carbons, BF₃, SF₆ and SiF₄.

6. The method of claim 1, wherein said second species is selected from the group consisting of NF₃, O₂ and He.

7. The method of claim 1, wherein said second implant region is inside said first implant region.

8. The method of claim 1, wherein said first implant region is inside said second implant region.

9. The method of claim 1, wherein said workpiece comprises 3D structures and said second implant region comprises vertical surfaces and horizontal surfaces.

10. The method of claim 9, wherein said first implant region comprises horizontal surfaces.

11. The method of claim 9, wherein said second implant is performed using a variety of implant angles.

12. The method of claim 1, wherein said first implant is performed before said second implant.

13. The method of claim 1, wherein said first implant is performed after said second implant.

14. A method of creating a workpiece having regions of differing surface energies, wherein said workpiece comprises 3D structures, comprising:
performing a first implant of a first species into vertical surfaces and horizontal surfaces of said 3D structures, and said first species increases the hydrophobicity of said first implant region; and
performing a second implant of a second species into said horizontal surfaces of said workpiece, wherein said second species reduces the hydrophobicity of said second implant region.

15. The method of claim 14, wherein said first implant is performed using a variety of implant angles.

16. The method of claim 14, wherein said first species is selected from the group consisting of fluorinated carbons, BF₃, SF₆ and SiF₄.

17. The method of claim 14, wherein said second species is selected from the group consisting of NF₃, O₂ and He.

18. A method of creating a workpiece having regions of differing surface energies, wherein said workpiece comprises 3D structures, comprising:
performing a first implant of a first species into vertical surfaces and horizontal surfaces of said 3D structures, and said first species reduces the hydrophobicity of said first implant region; and
performing a second implant of a second species into said horizontal surfaces of said workpiece, wherein said second species increases the hydrophobicity of said second implant region.

19. The method of claim 18, wherein said first implant is performed using a variety of implant angles.

20. The method of claim 18, wherein said second species is selected from the group consisting of fluorinated carbons, BF₃, SF₆ and SiF₄ and said first species is selected from the group consisting of NF₃, O₂ and He.
